(19) United States
(12) Patent Application Publication
(10) Pub. No.: US 2013/0271820 A1
(43) Pub. Date: Oct. 17, 2013

(54) ELECTROPHORETIC DISPLAY APPARATUS AND METHOD OF MANUFACTURING THE SAME

(71) Applicant: SEIKO EPSON CORPORATION, Tokyo (JP)

(72) Inventor: Hiroki NAKAHARA, Shiojiri-shi (JP)

(73) Assignee: SEIKO EPSON CORPORATION, Tokyo (JP)

(21) Appl. No.: 13/800,408

(22) Filed: Mar. 13, 2013

(30) Foreign Application Priority Data
Apr. 17, 2012 (JP) 2012-093913

(51) Int. Cl. G02F 1/167; H05K 3/40

(52) U.S. Cl. CPC G02F 1/167; H05K 3/4007
USPC 359/296; 29/830

(57) ABSTRACT

An electrophoretic display apparatus includes a first substrate, a second substrate, a first electrode, a second electrode, an electrophoretic layer interposed between a TFT array substrate and an opposed substrate, a terminal for the second electrode provided in the first substrate, a conductive portion electrically connected to the second electrode and provided from a first surface to a second surface of the second substrate, and a connection member that electrically connects the conductive portion with the terminal for the second electrode.

### BACKGROUND

1. Technical Field

The present invention relates to an electrophoretic display apparatus and a method of manufacturing the same.

2. Related Art

The electrophoretic display apparatus has a configuration in which an electrophoretic material is interposed between a pair of substrates each provided with an electrode. By generating an electric field between the electrodes of the pair of substrates, charged particles in the electrophoretic material are moved between the pair of substrates, thereby the charged particles perform the color display. The structure of an electrode connection portion for applying a predetermined voltage to the electrodes on each substrate is disclosed in JP-A-2011-118185 as described below.

JP-A-2011-118185 discloses an information display panel of a passive matrix display type as an example of a charged particle drive type information display panel. In the information display panel of the example, a flexible cable is used as a connection member adapted to connect the electrodes on each substrate with a drive circuit. Specifically, a terminal portion of a stripe electrode is provided in an end portion of an observation side substrate, and the wiring of the flexible cable is connected to the terminal portion. Similarly, the terminal portion of the stripe electrode is provided in an end portion of a back side substrate, and the wiring of the flexible cable is connected to the terminal portion. Furthermore, a seal material is provided between the pair of substrates so as to interpose the flexible cable from both sides at a position not coming into contact with the terminal portion on the substrate, in each flexible cable.

In the information display panel of JP-A-2011-118185, there is a need to connect the flexible cable to both of the pair of substrates. For that reason, there was a problem that the manufacturing costs increases for reasons such as an increase in the number of the components and complexity of the manufacturing process.

### SUMMARY

An advantage of some aspects of the invention is to provide an electrophoretic display apparatus having a simple configuration and a simple manufacturing process, and capable of reducing the manufacturing cost, and a method of manufacturing the same.

According to an aspect of the invention, there is provided an electrophoretic display apparatus which includes a first substrate; a second substrate facing the first substrate; an electrophoretic layer that is interposed between the first substrate and the second substrate and contains electrophoretic particles; a first electrode that is provided between the first substrate and the electrophoretic layer; a second electrode that is provided between the second substrate and the electrophoretic layer; a terminal for the second electrode that is provided in the first substrate and is electrically connected to the second electrode; a conductive portion that is electrically connected to the second electrode and is provided from a first surface side of the second substrate facing the first substrate to a second surface side not facing the first substrate; and a connection member that is connected to the conductive portion in a portion located on the second surface side of the second substrate in the conductive portion and electrically connects the conductive portion with the terminal for the second electrode.

According to the electrophoretic display apparatus of the aspect of the invention, it is possible to supply electric potential to the second electrode via the connection member and the conductive portion connected to the terminal for the second electrode. That is, it is possible to supply the electric potential to the second electrode provided in the second substrate from the terminal for the second electrode provided on the first substrate. For that reason, for example, it is enough to connect a flexible cable for external connection or the like only to the first substrate. For that reason, it is possible to provide an electrophoretic display apparatus having a simple configuration and manufacturing process capable of reducing the manufacturing cost.

In the electrophoretic display apparatus of the aspect of the invention, the conductive portion may be constituted by a conductive film that is provided from the first surface of the second substrate to the second surface via an end surface of the second substrate.

According to the configuration, the conductive portion constituted by the conductive film can be formed using the simple film forming method.

In the electrophoretic display apparatus of the aspect of the invention, a through hole may be provided which penetrates between the first surface and the second surface of the second substrate, and the conductive portion may be constituted by a conductor placed inside the through hole.

According to the configuration, since there is a form in which the conductive portion is buried inside the second substrate, the strong conductive portion can be formed.

In the electrophoretic display apparatus of the aspect of the invention, it is preferable that the first electrode is a plurality of pixel electrodes and the second electrode is a common electrode.

According to the configuration, it is possible to realize an electrophoretic display apparatus of an active matrix type.

According to a second aspect of the invention, there is provided a method of manufacturing an electrophoretic display apparatus, the method includes forming a first electrode and a terminal for a second electrode on a first substrate; forming a second electrode on a first surface of a second substrate; forming a conductive portion from the first surface to the second surface so as to be electrically connected to the second electrode with respect to the second substrate provided with the second electrode; adhering the first substrate and the second substrate in the state of interposing an electrophoretic layer including electrophoretic particles between the first substrate and the second substrate by causing the first electrode to face the second electrode; and connecting a connection member to a portion located on the second surface of the second substrate in the conductive portion and electrically connecting the conductive portion to the terminal for the second electrode via the connection member.

According to the method of manufacturing the electrophoretic display apparatus of the second aspect of the invention, it is possible to provide an electrophoretic display apparatus having a simple configuration and manufacturing process capable of reducing the manufacturing cost.

In the method of manufacturing the electrophoretic display apparatus of the aspect of the invention, in the formation of the conductive portion, the conductive portion may be formed using a plating method.

According to the configuration, it is possible to form the conductive portion formed of a conductive film using the simple film forming method called a plating method.

In the method of manufacturing the electrophoretic display apparatus of the second aspect of the invention, in the formation of the conductive portion, a thorough hole penetrating between the first surface and the second surface of the second substrate may be formed, the conductor protruding to the outside of the first surface and the second surface of the second substrate may be placed inside the through hole, and the conductive portion may be formed, by crimping the protrusion portion of the conductor.

According to the configuration, the conductive portion of the form buried into the second substrate is formed, and thus the strong conductive portion can be formed.

### BRIEF DESCRIPTION OF THE DRAWINGS

The invention will be described with reference to the accompanying drawings, wherein like numbers reference like elements.

FIG. 1 is a plan view that shows an electrophoretic display apparatus of Embodiment 1 of the invention.

FIG. 2 is a cross-sectional view taken along a line II-II of FIG. 1.

FIGS. 3A to 3E are cross-sectional views that show a method of manufacturing the electrophoretic display apparatus of the embodiment according to a process order.

FIG. 4 is a plan view that shows an electrophoretic display apparatus of Embodiment 2 of the invention.

FIG. 5 is a cross-sectional view taken along a line V-V of FIG. 4.

FIGS. 6A to 6D are cross-sectional views that show a method of manufacturing the electrophoretic display apparatus of the embodiment according to a process order.

FIGS. 7A to 7C are perspective views that show specific examples of an electronic device to which the electrophoretic display apparatus of the invention is applied, FIG. 7A is a perspective view that shows an electronic book, FIG. 7B is a perspective view that shows a wrist watch, and FIG. 7C is a perspective view that shows an electronic paper.

### DESCRIPTION OF EXEMPLARY EMBODIMENTS

### Embodiment 1

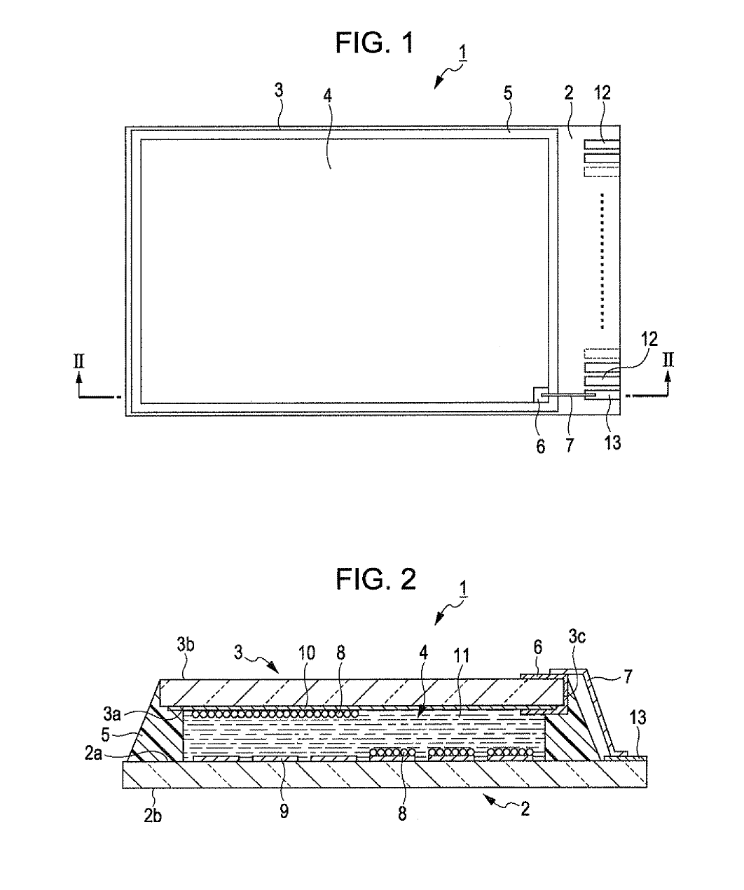

Hereinafter, Embodiment 1 of the invention will be described using FIGS. 1 to 3E.

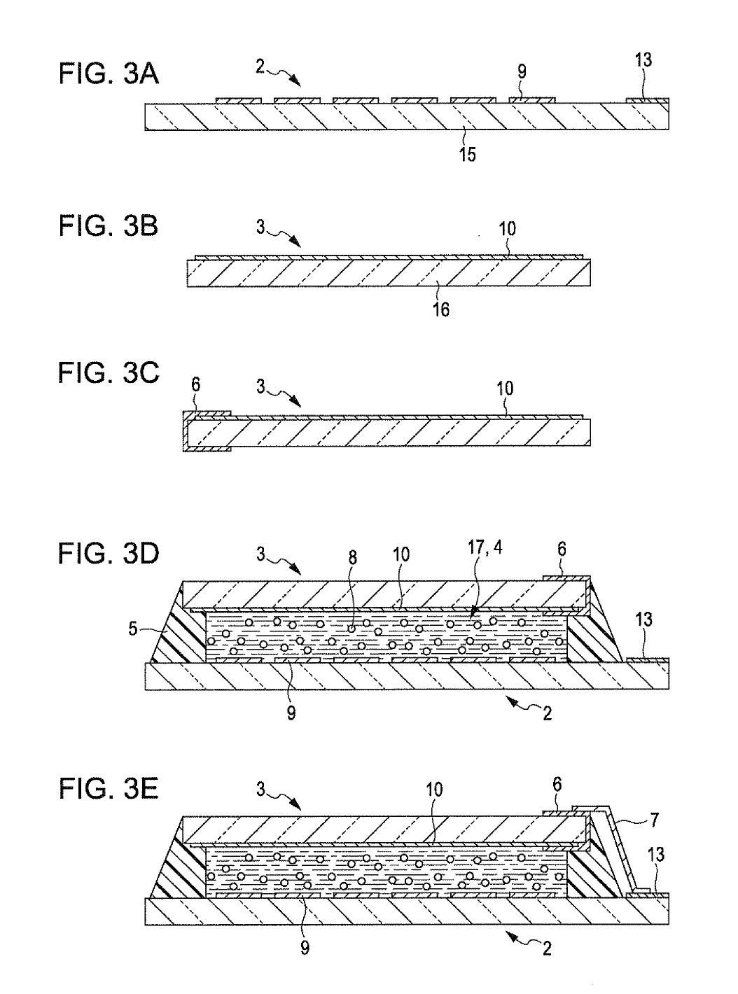

FIG. 1 is a plan view that shows an electrophoretic display apparatus of the embodiment of the invention. FIG. 2 is a cross-sectional view taken along a line II-II of FIG. 1. FIGS. 3A to 3E are cross-sectional views that show a method of manufacturing the electrophoretic display apparatus of the embodiment according to a process order.

In addition, in the respective following drawings, in order to easily see each component, in some cases, the reduced scales of the dimensions may be different according to the components.

As shown in. FIGS. 1 and 2, the electrophoretic display apparatus 1 of the embodiment includes a thin film transistor (hereinafter, outlined as TFT) array substrate 2 (a first substrate), an opposed substrate 3 (a second substrate), an electrophoretic layer 4, an outer circumferential seal material 5, a conductive portion 6, and a common electric potential supply wiring 7 (a connection member). The TFT array substrate 2 and the opposed substrate 3 are placed so as to face each other and are adhered to each other by the outer circumferential seal material 5 provided on the peripheral edge portions of the substrates 2 and 3 at a predetermined interval.

In a space surrounded by the TFT array substrate 2, the opposed substrate 3 and the outer circumferential seal material 5, an electrophoretic material including electrophoretic particles 8 is enclosed to form the electrophoretic layer 4. In the following description, surfaces 2a and 3a of the sides of the TFT array substrate 2 and the opposed substrate 3 coming into contact with the electrophoretic layer 4 are each referred to as inner surfaces, and surfaces 2b and 3b of an opposite side to the side coming into contact with the electrophoretic layer 4 are each referred to as outer surfaces. The inner surface 3a of the opposed substrate 3 corresponds to a first surface of the claims, and the outer surface 3b of the opposed surface 3 corresponds to a second surface of the claims.

On the inner surface 2a of the TFT array substrate 2, a data line, a scanning line, the TFT or the like (not shown) are formed. The configuration of the TFT array substrate 2 is well known, although the detailed description thereof will be omitted, a plurality of data lines and a plurality of scanning lines are placed so as to intersect each other, and each region surrounded by the data lines adjacent to each other and the scanning lines adjacent to each other are pixels. The TFT is placed for each pixel, and a pixel electrode is connected to each TFT. Thus, as shown in FIG. 2, on the inner surface 2a of the TFT array substrate 2, a plurality of pixel electrodes 9 (a first electrode) is formed.

The TFT array substrate 2 is constituted by, for example, a glass substrate. However, the material of the TFT array substrate 2 can also use other materials, for example, various plastic substrates, without being limited to the glass substrate. In addition, the material of the TFT array substrate 2 may not be necessarily a transparent material. For example, the pixel electrode 9 is constituted by a transparent conductive film such as indium tin oxide (hereinafter, outlined as ITO). In addition, the material of the pixel electrode 9 can also use other transparent conductive films, without being limited to the ITO. In addition, the material of the pixel electrode 9 may not necessarily be the transparent conductive material.

As shown in FIG. 2, on the inner surface 3a of the opposed substrate 3, a common electrode 10 (a second electrode) is formed. The common electrode 10 is an electrode that is common to all pixels, and is formed at least over the whole area of the display region. For example, the opposed substrate 3 is constituted by a glass substrate. In addition, the material of the opposed substrate 3 can also use other materials, for example, plastic films such as polyethylene terephthalate (PET), ABS resin and polyimide, without being limited to the glass substrate. As will be described later, although the plating treatment is applied to a part of the opposed substrate, the plating treatment can also be applied to the plastic films as well as the glass substrate. For example, the common electrode 10 is constituted by a transparent conductive film such as ITO. In addition, the material of the common electrode 10 can also use other transparent conductive films, for example, such as IZO, without being limited to the ITO.

The materials of the pixel electrode 9 and the common electrode 10 are selected so that a difference of the Fermi level of the electrodes decreases. The reason is that the difference of the Fermi level becomes the direct current voltage to cause the corrosion of the electrodes. For example, when forming the electrode of ITO and the electrode of aluminum, it is known that the corrosion occurs due to the direct current voltage. For this reason, for example, it is the most desirable to form the pixel electrode 9 and the common electrode 10 by the same material.

The outer circumferential seal material 5 is placed between the TFT array substrate 2 and the opposed substrate 3, and the TFT array substrate 2 and the opposed substrate 3 are maintained using the outer circumferential seal material 5 at a predetermined interval. As the outer circumferential seal material 5, a seal material of a liquid crystal panel can be used, and, for example, a UV-curing type acryl-based resin is used. Otherwise, a thermosetting type epoxy-based resin may be used.

The electrophoretic material forming the electrophoretic layer 4 includes a transparent disperse medium 11, and the electrophoretic particles 8, for example, of black dispersed in the disperse medium 11 and charged with positive electricity. For example, the disperse medium 11 is silicon oil, and the electrophoretic particles 8 are particles in which, for example, a charged group is formed on the surface of the acryl particle colored in black. The charging degree and the dispersion degree of the electrophoretic material can be adjusted by a charging agent and a dispersing agent added to the electrophoretic material.

The electrophoretic particles 8 can move between both electrodes 9 and 10 based on the difference of the electric potential between the pixel electrode 9 and the common electrode 10, and can be electrically adsorbed with respect to the pixel electrode 9 and the common electrode 10 as shown in FIG. 2. In the electrophoretic display apparatus 1 of the embodiment, although a microcapsule and a partition for partitioning the electrophoretic layer 4 for each region are not provided, the microcapsule and the partition may be provided. Furthermore, the electrophoretic material including the particles not charged may be used other than the electrophoretic particles 8.

As shown in FIG. 1, the dimension of the TFT array substrate 2 in the longitudinal direction is greater than that of the opposed substrate 3 in the longitudinal direction, and an end portion (a right end portion in FIG. 1) of a short side of the TFT array substrate 2 protrudes to the outside of the opposed substrate 3. In the protruding portion on the inner surface of the TFT array substrate 2, a terminal portion 12 for supplying the signal to the data line and the scanning line on the TFT array substrate 2, and a terminal 13 for the common electrode (a terminal for the second electrode) for supplying the common electric potential to the common electrode 10 on the opposed substrate 3 are formed. The terminal 13 for the common electrode is electrically connected to the common electrode 10 by a connection structure which will be described later.

As shown in FIG. 1, among the four corner portions of the opposed substrate 3, one corner portion is provided with the conductive portion 6. Herein, although the plane shape of the conductive portion 6 was a rectangular shape, the shape is not particularly limited. For example, the conductive portion 6 is constituted by a conductive film formed of a metal such as copper (Cu), nickel (Ni), and palladium (Pd). As shown in FIG. 2, the conductive portion 6 is provided from the inner surface 3a of the opposed substrate 3 to the outer surface 3b via the end surface 3c so as to come into contact with the end portion of the common electrode 10. With such a configuration, the conductive portion 6 is electrically connected to the common electrode 10.

The conductive portion 6 of the opposed substrate 3 and the terminal 13 for the common electrode of the TFT array substrate 2 are electrically connected to each other by a common electric potential supply wiring 7. The common electric potential supply wiring 7 is a wiring, for example, formed of a metal such as copper (Cu), silver (Ag), and aluminum (Al). As the form of the wiring, for example, a tape shape and a bonding wire shape may be used. One end of the common electric potential supply wiring 7 is electrically connected to the conductive portion 6 in a portion placed on the outer surface 3b of the opposed substrate 3. The other end of the common electric potential supply wiring 7 is electrically connected to the terminal 13 for the common electrode on the TFT array substrate 2.

In addition, although not shown in FIG. 1, a flexible substrate is connected to the terminal portion 12 of the TFT array substrate 2 and the terminal 13 for the common electrode. In the flexible substrate, drive circuits such as a data line drive circuit and a scanning line drive circuit, a controller (a control unit) or the like are implemented. Thus, various signals for driving the electrophoretic display apparatus 1 is supplied to the TFT array substrate 2 from the flexible substrate.

Hereinafter, a method of manufacturing the electrophoretic display apparatus 1 of the present embodiment will be described.

First, as shown in FIG. 3A, on one surface of the substrate 15 serving as the TFT array substrate 2 later, a data line, a scanning line and a TFT (not shown) are formed. Since a general well-known process is used in such a forming method, the description and the illustration thereof will be omitted. Next, on the one surface of the substrate 15, the conductive film such as an ITO is formed using the sputtering method, and a plurality of pixel electrodes 9 is formed by patterning the conductive film. Furthermore, the terminal 13 for the common electrode is formed on the one surface of the substrate 15. The terminal 13 for the common electrode may be formed concurrently with the data line, the scanning line, the pixel electrode or the like, and may be formed by separate processes. By the above-mentioned processes, the TFT array substrate 2 is completed.

Meanwhile, as shown in FIG. 3B, the common electrode 10 is formed on one surface of the glass substrate 16 serving as the opposed substrate 3 later. At this time, the conductive film such as the ITO is formed on the one surface of glass substrate 16 using the sputtering method or the like, and the common electrode 10 is formed by patterning the conductive film. By the above-mentioned processes, the opposed substrate 3 is completed.

Next, as shown in FIG. 3C, the conductive film such as copper, nickel and palladium are formed on one corner portion of the opposed substrate 3 throughout both surfaces and the end surface of the opposed substrate 3 using the plating method so as to be used as the conductive portion 6. When forming the conductive portion 6, an electrolysis plating method may be used, and an electroless plating method may be used. Even when using any plating method, by immersing one corner portion of the opposed substrate 3 in plating solution, the conductive film can be selectively formed in this portion.

Next, as shown in FIG. 3D, in the state of causing the pixel electrode 9 to face the common electrode 10 and interposing the electrophoretic material 17 including the electrophoretic particles 8 between the TFT array substrate 2 and the opposed substrate 3, the TFT array substrate 2 and the opposed substrate 3 are adhered to each other via the outer circumferential seal material 5. At this time, for example, an ultraviolet (UV) curing resin is drawn in a frame shape in the peripheral portion of the TFT array substrate 2 using a dispenser method or the like, thereby to form the outer circumferential seal material 5. After that, the electrophoretic material 17 drops down in the region surrounded by the outer circumferential seal material 5 on the TFT array substrate 2, and the opposed substrate 3 is placed over the outer circumferential seal material 5. After that, the outer circumferential seal material 5 is irradiated with ultraviolet ray, and the outer circumferential seal material 5 is cured. Thereby, the electrophoretic material 17 is enclosed between the TFT array substrate 2 and the opposed substrate 3, and thus the electrophoretic layer 4 is formed.

Next, as shown in FIG. 3E, in the conductive portion 6, one end of the common electric potential supply wiring 7 is connected to the portion located on the outer surface of the opposed substrate 3, and the other end of the common electric potential supply wiring 7 is connected to the terminal 13 for the common electrode on the TFT array substrate 2. In this manner, the conductive portion 6 and the terminal 13 for the common electrode are electrically connected to each other via the common electric potential supply wiring 7. The connection of the common electric potential supply wiring 7 can be performed, for example, using a wire bonding method or the like.

For example, even in the liquid crystal display device, in some cases, the connection structure may be provided between the two substrates so as to supply the common electric potential to the common electrode. In the case of the liquid crystal display device, since the interval between the two substrates is extremely narrow, for example, several pm, it is relatively easy to place the conductive material such as a metal on the facing surfaces of the two substrates to take the conduction. However, in the case of the electrophoretic display apparatus, the interval between the two substrates is much wider than that of the liquid crystal display device, and thus it is difficult to thickly place the conductive material on the facing surfaces of the two substrates to perform the electrical connection.

In this respect, according to the electrophoretic display apparatus 1 of the embodiment, it is possible to supply the common electric potential to the common electrode 10 via the common electric potential supply wiring 7 and the conductive portion 6. For that reason, it is enough to connect the flexible substrate or the like, on which a drive circuit such as a controller is implemented, only to the TFT array substrate 2. For that reason, thus it is possible to provide the electrophoretic display apparatus 1 in which the configuration of the module and the manufacturing process are simple, and which is capable of reducing the manufacturing cost. Furthermore, according to the manufacturing method of the embodiment, it is possible to easily form the conductive portion 6 on the opposed substrate 3 using the plating method.

### Embodiment 2

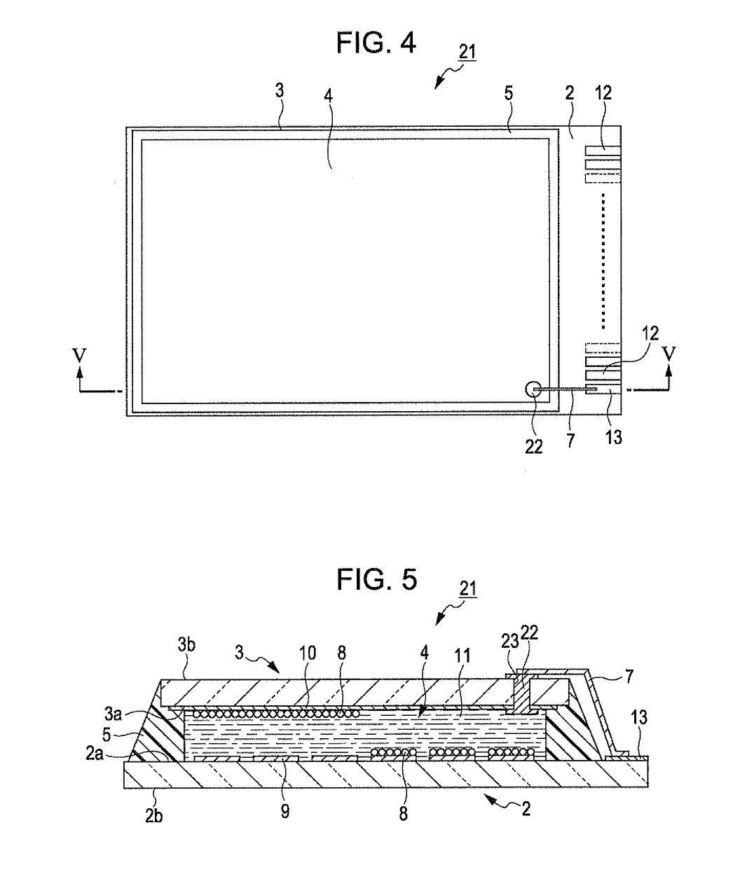

Hereinafter, Embodiment 2 of the invention will be described using FIGS. 4 to 6D.

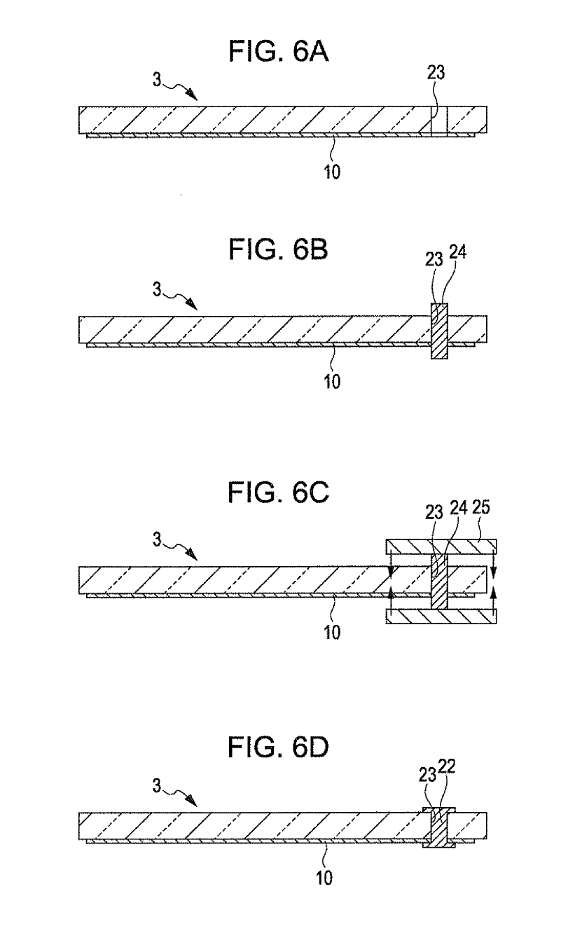

FIG. 4 is a plan view that shows the electrophoretic display apparatus of the embodiment. FIG. 5 is a cross-sectional view taken along a line V-V of FIG. 4. FIGS. 6A to 6D are cross-sectional views that show a method of manufacturing the electrophoretic display apparatus of the embodiment according to a process order.

In addition, in FIGS. 4 to 6D, the components common to the drawings used in Embodiment 1 are denoted by the same reference numerals, and the descriptions thereof will be omitted.

In the electrophoretic display apparatus 21 of the embodiment, as shown in FIGS. 4 and 5, in one corner portion of the opposed substrate 3, a though hole 23 penetrating between the inner surface 3a and the outer surface 3b of the opposed substrate 3 is provided. The conductive portion 22 is formed of a metal (a conductor) such as copper (Cu) and aluminum (Al) filled inside the through hole 23. The upper end and the lower end of the conductive portion 22 are formed so as to come into contact with the inner surface 3a and the outer surface 3b of the opposed substrate 3, and are formed to have a diameter that is greater than that of the portion located inside the through hole 23. That is, the conductive portion 22 is formed throughout the inner surface 3a and the outer surface 3b of the opposed substrate 3, and is electrically connected to the common electrode 10. Other configurations are the same as those of Embodiment 1.

Hereinafter, the method of manufacturing the electrophoretic display apparatus 21 of the embodiment will be described.

The method of manufacturing the electrophoretic display apparatus 21 of the embodiment is basically the same as that of Embodiment 1, and only forming the conductive portion 22 is different from that of Embodiment 1. Thus, herein, only forming the conductive portion 22 will be described.

After manufacturing the opposed substrate 3, as shown in FIG. 6A, the though hole 23 is formed in one corner portion of the opposed substrate 3. In Embodiment 1, glass and plastic were described as examples of the opposed substrate 3. However, in the embodiment, as the material of the opposed substrate 3, for example, it is suitable to use a plastic film having a thin plate thickness such as polyethylene terephthalate (PET). The reason is that, when using this kind of plastic film, the though hole 23 is easily opened using the simple method, and the defect such as missing of the periphery of the through hole 23 is hard to occur.

Next, as shown in FIG. 6B, a metallic piece 24 such as copper (Cu) and aluminum (Al) having the height slightly higher than that of the plate thickness of the opposed substrate 3 is charged into the through hole 23. At this time, the upper end and the lower end of the metallic piece 24 are in the state of protruding outward from both surfaces of the opposed substrate 3.

Next, as shown in FIG. 6C, the protruding portion of the metallic piece 24 is crimped using a tool such as a crimper 25.

Thereby, as shown in FIG. 6D, the upper end and the lower end of the metallic piece 24 are destroyed and the diameters thereof become greater than those of the portion located inside the through hole 23. As a result, the conductive portion 22 electrically connected to the common electrode 10 is formed.

Other processes are the same as those of Embodiment 1.

In the embodiment, it is also possible to obtain the same effect as Embodiment 1 that can provide an electrophoretic display apparatus in which the configuration of the module and the manufacturing process are simple and which is capable of reducing the manufacturing cost. Furthermore, according to the method of manufacturing of the embodiment, the conductive portion 22 can be easily formed by crimping the metallic piece 24 using the crimper 25 or the like.

### Electronic Device

Next, a case of applying the electrophoretic display apparatus of each of the above-mentioned embodiments to the electronic device will be described.

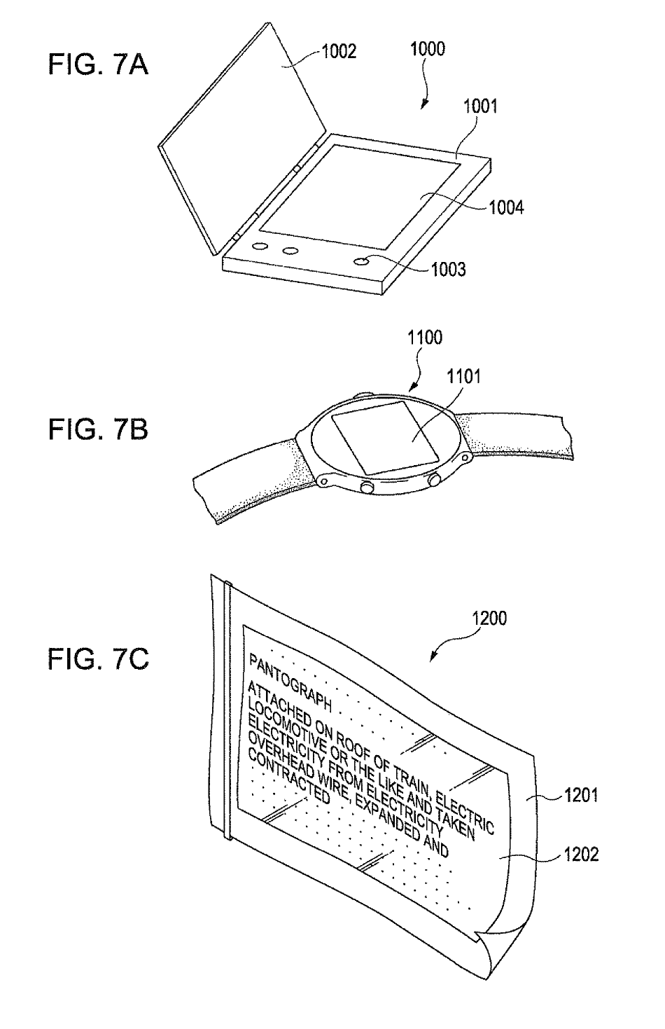

FIGS. 7A to 7C are perspective views that show specific examples of the electronic device to which the electrophoretic display apparatus of the invention is applied.

FIG. 7A is a perspective view that shows an electronic book as an example of the electronic device. The electronic book 1000 includes a book-shaped frame 1001, an operation product 1003, a cover 1002 provided so as to be freely rotatable (openable and closeable) with respect to the frame 1001, and a display portion 1004 constituted by the electrophoretic display apparatus of the above-mentioned embodiments.

FIG. 7B is a perspective view that shows a wrist watch as an example of the electronic device. The wrist watch 1100 includes a display portion 1101 constituted by the electrophoretic display apparatus of the above-mentioned embodiments.

FIG. 7C is a perspective view that shows an electronic paper as an example of the electronic device. The electronic paper 1200 includes a main body portion 1201 constituted by a rewritable sheet having a texture and flexibility like the paper, and a display portion 1202 constituted by the electrophoretic display apparatus of the above-mentioned embodiments.

For example, since it is assumed that the electronic book, the electronic paper or the like has a usage for repeatedly writing letters on a background of a blank, there is a need for the cancellation of an afterimage and a time-dependent afterimage at the time of removal.

In addition, the range of the electronic device, to which the electrophoretic display apparatus of the invention can be applied, widely includes apparatuses that use the change of the color in sight along with the movement of the charged particles, without being limited thereto.

According to the electronic book 1000, the wrist watch 1100 and the electronic paper 1200 mentioned above, since the electrophoretic display apparatus related to the above-mentioned embodiments is adopted, the cheap electronic device can be provided.

In addition, the above-mentioned electronic device does not limit the technical scope of the invention. For example, it is also possible to suitably use the electrophoretic display apparatus related to the invention, in the display portion of the electronic device such as a mobile phone and a portable audio device, a sheet for business such as a manual, a textbook, a question collection, an information sheet or the like.

In addition, the technical scope of the invention is not limited to the above-mentioned embodiments, and various modifications can be made within the scope that does not depart from the gist of the invention.

For example, in the above-mentioned embodiments, although examples have been described in which the conductive portion is formed only in one corner portion of the opposed substrate, the number of the conductive portion is not limited to one, but a plurality of conductive portions may be provided. Furthermore, the forming position of the conductive position is not limited to the corner portion of the opposed substrate but may be other positions. The numbers, the arrangements, the materials, the forming methods or the like of various components of the electrophoretic display apparatus can be suitably changed, without being limited to the above-mentioned embodiments.

The entire disclosure of Japanese Patent Application No. 2012-093913, filed Apr. 17, 2012 is expressly incorporated by reference herein.

What is claimed is:

1. An electrophoretic display apparatus comprising:
a first substrate;
a second substrate facing the first substrate;
an electrophoretic layer that is interposed between the first substrate and the second substrate and contains electrophoretic particles;
a first electrode that is provided between the first substrate and the electrophoretic layer;
a second electrode that is provided between the second substrate and the electrophoretic layer;
a terminal for a second electrode that is provided in the first substrate and is electrically connected to the second electrode;
a conductive portion that is electrically connected to the second electrode and is provided from a first surface side of the second substrate facing the first substrate to a second surface side thereof not facing the first substrate; and
a connection member that is connected to the conductive portion in a portion located on the second surface side of the second substrate in the conductive portion and electrically connects the conductive portion with the terminal for the second electrode.

2. The electrophoretic display apparatus according to claim 1,
wherein the conductive portion is constituted by a conductive film that is provided from the first surface of the second substrate to the second surface via an end surface of the second substrate.

3. The electrophoretic display apparatus according to claim 1,
wherein a through hole is provided which penetrates between the first surface and the second surface of the second substrate, and
the conductive portion is constituted by a conductor that is placed inside the through hole.

4. The electrophoretic display apparatus according to claim 1,
wherein the first electrode has a plurality of pixel electrodes, and the second electrode is a common electrode.

5. A method of manufacturing an electrophoretic display apparatus, comprising:
forming a first electrode and a terminal for a second electrode on a first substrate;
forming the second electrode on a first surface of a second substrate;
forming a conductive portion from the first surface to the second surface so as to be electrically connected to the second electrode with respect to the second substrate provided with the second electrode;
adhering the first substrate and the second substrate, in the state of interposing an electrophoretic layer including electrophoretic particles between the first substrate and the second substrate by causing the first electrode to face the second electrode; and
connecting a connection member to a portion located on the second surface of the second substrate in the conductive portion to electrically connect the conductive portion and the terminal for the second electrode via the connection member.

6. The method of manufacturing the electrophoretic display apparatus according to claim 5,
wherein, in the formation of the conductive portion, the conductive portion is formed using a plating method.

7. The method of manufacturing the electrophoretic display apparatus according to claim 5,
wherein, in the formation of the conductive portion, a thorough hole penetrating between the first surface and the second surface of the second substrate is formed, a conductor protruding to the outside of the first surface and the second surface of the second substrate is placed inside the through hole, and the conductive portion is formed by crimping a protrusion portion of the conductor.
